(19) United States
(12) Patent Application Publication
(10) Pub. No.: US 2026/0309759 A1
(43) Pub. Date: Oct. 8, 2026

(54) VOLTAGE DROP AND CAPACITY USE CALCULATION SYSTEM

(71) Applicant: BASARSOFT BILGI TEKNOLOJILERI ANONIM SIRKETI, Cankaya, Ankara (TR)

(72) Inventor: Tuncay KUCUKPEHLIVAN, Cankaya, Ankara (TR)

(21) Appl. No.: 19/161,659

(22) PCT Filed: Dec. 9, 2024
(86) PCT No.: PCT/TR2024/051515

§ 371 Date: Sep. 2, 2025

(30) Foreign Application Priority Data
Dec. 25, 2023 (TR) 2023/018382

(51) Int. Cl. G01R 21/133; G01R 22/06; G01R 22/10; H02J 13/12

(52) U.S. Cl. CPC G01R 21/1338; G01R 22/063; G01R 22/10; H02J 13/12

(57) ABSTRACT

A system for the calculation of voltage drop and capacity use in a low voltage network from subscriber consumption data.

### TECHNICAL FIELD OF THE INVENTION

The invention relates to the calculation of voltage drop and capacity use in the low voltage network from subscriber consumption data.

### THE STATE OF THE ART

In the planning phase of the low voltage network, the amount of load to be realised is estimated according to the population density and construction information in the zoning plans, and conductor selection and voltage drop calculations are made on these estimated loads. Due to changes in zoning plans, the plans made need to be revised from time to time.

In the operation phase, the amount of load on the conductor is tried to be estimated using diversity factors according to the installed powers of the customers and the number of customers.

Voltage drop and line capacity amount are important factors in order to provide quality energy to the customer. The standard accepted worldwide is that the voltage drop should not exceed 5%. Low voltage causes the failure of electronic devices and excessive load consumption. For this reason, when a new customer or power increase request occurs, distribution companies go to the customer's location and give energy connection permission after taking measurements.

For the current voltage drop calculation, either CAD-based applications are used or the necessary data for voltage drop calculation is entered into excel tables on excel. In both cases, the data is realised by transferring data from either maps or the GIS system. Existing voltage drop software works and makes predictions using data from zoning plans. On the existing network, these calculations use the diversity coefficient according to the total installed power fed through the line and the number of customers, so it is not known whether the calculated data is realised on the network. A customer having 5 kW installed power does not indicate that they have 5 kW consumption. For this reason, distribution companies often connect energy analysers to the point where energy is requested and make a connection permission, that is, increase the power, after observing for a certain period of time. However, since the measurement time may not be the maximum consumption time experienced in that region, this measurement cannot provide a definite idea either.

The invention in the application numbered “US2015149396A1” in the state of the art relates to the field of electrical energy distribution systems and more specifically to the detection and localisation of non-technical losses in electrical power distribution systems. In the event of theft, extra power flows through the feeder and/or feeders, and this situation is determined by comparing the estimated voltage at the node points with the voltage measured on the smart meter.

The invention in the application numbered “CN101958544” in the state of the art relates to the theoretical line loss calculation of a distribution network. It provides a system and method for calculating the line loss rate of an electrical power distribution line that can calculate the line loss rate of a distribution network relatively quickly and accurately.

In the state of the art, there are documents containing voltage drop monitoring. However, there is no system that calculates the load on each conductor and the voltage drop caused by this load using customer invoice information and meter reading system data in transformers without the need for additional measurement. While it is assumed that each customer has a fixed consumption in this process carried out on the currently installed powers, the actual consumption data of each customer is used with the invention that is the subject to the current application. In this way, both the occupancy rate of the conductor capacity and the voltage drop at the end of the line can be calculated, and how the voltage drop and capacity use change in the event of additional load can be calculated.

As a result, due to the negativities described above and the inadequacy of existing solutions on the subject, it has become necessary to make a development in the relevant technical field.

### BRIEF DESCRIPTION AND AIMS OF THE INVENTION

The invention relates to the calculation of voltage drop and capacity use in the low voltage network from subscriber consumption data.

The most important aim of the invention is to be able to calculate the load on each conductor and the voltage drop caused by this load using customer billing information and meter reading system data in transformers without the need for additional measurement.

Another aim of the invention is to enable the calculation of both the conductor capacity occupancy rate and the voltage drop at the end of the line by using the actual consumption data of each customer.

Another aim of the invention is to enable the calculation of the amount of load passing through all conductors in the network, that is, the occupancy rate of the line and the voltage drop at the end of the line, without the need for field measurement.

### DESCRIPTION OF THE DRAWINGS

FIG. 1 is the drawing that gives the schematic view of the voltage drop and capacity use calculation system which is the subject of the invention.

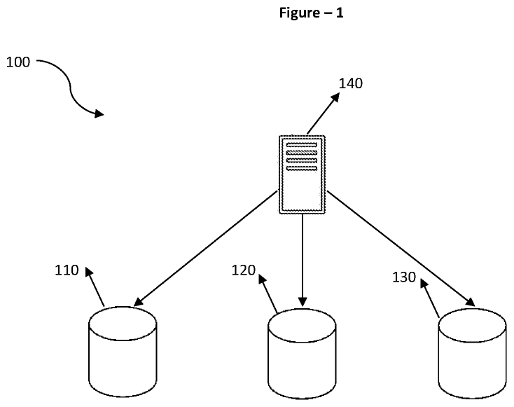

### REFERENCE NUMBERS

100. Voltage drop and capacity use calculation system
110. Subscriber information management system
120. Automatic meter reading system
130. Geographic information system
140. Server

### Description of the Invention

The invention relates to the calculation of voltage drop and capacity use in the low voltage network from subscriber consumption data.

With the developed voltage drop and capacity use calculation system (100), daily average consumption data is obtained from customer invoice index data. The total daily consumption value of all customers fed from a transformer is obtained. Then, for each low voltage conductor in the transformer area, all customer data fed from that conductor and the average consumption of these customers are obtained. The total transformer consumption and the total consumption on this conductor are proportioned to the maximum consumption of the transformer and how much of the maximum transformer consumption passes through this conductor is calculated. This value is the amount of load that will pass through that conductor when there is peak consumption. Since the voltage drop calculation to be made with the obtained load data is synthesised from the actual transformer consumption data, it produces a more realistic result compared to the calculations made on the installed power.

The subscriber information management system (110) records the electricity consumption of the subscribers. The subscriber information management system (110) is used by electricity distribution companies to record the customer types and consumption data of electricity subscribers.

The automatic meter reading system (120) enables the reading of consumption data from transformer meters and the recording of peak consumption data.

The geographic information system (130) records the locations of electricity subscriber customers and transformer locations.

The server (140) is in communication with the subscriber information management system (110), the automatic meter reading system (120) and the geographic information system (130). The server (140) receives the subscribers' consumption information from the subscriber information management system (110). The server (140) receives the transformers' consumption data and peak consumption value from the automatic meter reading system (120). The server (140) receives location information of subscribers and location information of transformers from the geographic information system (130). The server (140) determines which subscribers receive service from which transformer based on location with the customer location information it receives from the geographic information system (130). The server (140) calculates the average total consumption of all customers fed by that conductor for each low voltage conductor in the transformer area.

The customer daily average consumption is calculated by the server (140) with the equation=(reading index−previous reading index)/(reading date/previous reading date).

The reading index is the last measured index value. The previous reading index is the measurement value before the last measurement. The date on which the reading index is read is the reading date, and the date on which the previous reading index is read constitutes the previous reading date. When the difference between the two indices is divided by the days between the readings of the two indices, the customer daily average consumption is found.

The load on a conductor is calculated by the server (140) with the equation=((total daily average consumption of customers fed from that conductor/total daily consumption of all customers on the transformer)*measured peak load).

1. Voltage drop and capacity use calculation system that enables the calculation of voltage drop and capacity use in a low voltage network from subscriber consumption data, the system comprising:
at least one subscriber information management system that records customer types and consumption data of electricity subscribers;
at least one automatic meter reading system that enables reading consumption data from transformer meters and recording of peak consumption data;
at least one geographic information system that records locations of electricity subscriber customers and transformer locations; and
at least one server that, in communication with the at least one subscriber information management system, the at least one automatic meter reading system and the at least one geographic information system, calculates an daily average total consumption of all customers fed from that conductor and the load passing through a conductor for each low voltage conductor in the transformer area by receiving the consumption information of the subscribers from the subscriber information management system, the consumption data and peak consumption value of the transformers from the automatic meter reading system, and the location information of the subscribers and the location information of the transformers from the geographic information system.

2. The system that allows the calculation of voltage drop and capacity use in the low voltage network from subscriber consumption data of claim 1, wherein the daily average consumption total of the customers is calculated by the server with the equation (reading index−previous reading index)/(reading date/previous reading date).

3. The system that allows the calculation of voltage drop and capacity use in the low voltage network from subscriber consumption data of claim 1, wherein the load passing through a conductor is calculated by the server with the equation ((total daily average consumption of the customer/total daily consumption of all customers in the transformer)*measured peak load).
